(19) United States
(12) Patent Application Publication
(10) Pub. No.: US 2013/0168832 A1
(43) Pub. Date: Jul. 4, 2013

(54) SEMICONDUCTOR DEVICE

(71) Applicant: Mitsuyoshi ENDO, Kanagawa-ken (JP)

(72) Inventor: Mitsuyoshi ENDO, Kanagawa-ken (JP)

(73) Assignee: KABUSHIKI KAISHA TOSHIBA, Tokyo (JP)

(21) Appl. No.: 13/606,724

(22) Filed: Sep. 7, 2012

(30) Foreign Application Priority Data
Jan. 4, 2012 (JP) P2012-000235

(51) Int. Cl. H01L 23/48; H01L 21/768

(52) U.S. Cl. 257/621; 438/667; 257/E23.011; 257/E21.597

(57) ABSTRACT

According to one embodiment, a semiconductor device is provided such that a penetrating via with a conductive material embedded through a medium of an insulating film is formed in a through hole of a p-type semiconductor substrate. The semiconductor device includes an n-type well on an upper section of the p-type semiconductor substrate in the vicinity of the penetrating via, an electrode connected to the n-type well, and the electrode connected to the p-type semiconductor substrate in the vicinity of the electrode.

### CROSS-REFERENCE TO RELATED APPLICATION

This application is based upon and claims the benefit of priority from Japanese Patent Application No. 2012-000235, filed Jan. 4, 2012; the entire contents of which are incorporated herein by reference.

### FIELD

Embodiments described herein relate to a semiconductor device.

### BACKGROUND

In nonvolatile semiconductor memory such as NAND type flash memory, to increase capacity across a two dimensional space, it is proposed to provide 3-dimensional laminated stacks of semiconductor chip, such as a memory chip. Each of the semiconductor chips includes a penetrating via to penetrate through the semiconductor substrate from a back side to a device side thereof, whereby the device surface and a via pad on the back surface of the semiconductor substrate are electrically connected. And then, by joining semiconductor chips in such a way to connect the via pad in between adjacent stacked semiconductor chips, the 3-dimensional stacked structure of a semiconductor device is obtained.

Since semiconductor substrates are electrically conductive, penetrating via or via pads need to be electrically insulated from the semiconductor substrate; therefore, an insulating film is interposed between substrate and the via and via pad. In this kind of structure, it is unavoidable to have high electrical capacity between the penetrating via or via pad and the surrounding semiconductor substrate. When a high frequency electrical signal is transmitted to a penetrating via, this electrical capacitance causes the signal waveform to blunt. To lower this electrical capacitance, forming a semiconductor layer around the insulating film having opposite conductivity type to that of the substrate is being proposed.

With conventional technology, the parasitic capacitance of the penetrating via is reduced by forming a depletion layer by forming a semiconductor layer of opposite conductivity type around the insulating film extending in the depth direction of the semiconductor substrate. However, with this method, a concern is that the formed depletion layer is thin and unable to sufficiently reduce parasitic capacitance. Additionally, forming a semiconductor layer of opposite conductivity type perpendicular to the semiconductor substrate using a method such as ion implantation, is a difficult process. With this method, the increase in cost is also a problem.

### DESCRIPTION OF THE DRAWINGS

FIGS. 1A and 1B are sectional schematic views of the structure of the semiconductor device in the first embodiment.

FIGS. 2A and 2B are sectional schematic views of the condition where reverse bias is applied to p-n junction.

FIG. 3 depicts a schematic sectional view of another configuration example of the semiconductor device in the first embodiment.

FIGS. 4A and 4B are a schematic sectional view of an example of the procedure of the manufacturing method of the semiconductor device in the first embodiment.

FIGS. 4C to 4E are a schematic sectional view of an example of the procedure of the manufacturing method of the semiconductor device in the first embodiment.

FIG. 5 depicts a schematic sectional view of another configuration example of the semiconductor device in the first embodiment.

FIG. 6 depicts a schematic diagram of the structure of the semiconductor device in the second embodiment.

FIGS. 7A and 7B are a schematic plane sectional view of the structure of the semiconductor device in the third embodiment.

### DETAILED DESCRIPTION

In general, referring to the drawings provided to further explain the semiconductor device relating to the embodiment, the sectional views of the semiconductor device are presented schematically and the relationship of thickness and width of the layers and ratio of the thickness of each layer may be different from the actual model. Moreover, the embodiments are disclosed to describe, not limit, the scope of the possible embodiment.

According to the embodiments, there is provided a semiconductor device that has a conductive penetrating via embedded through an insulating film within the through hole of the semiconductor substrate, one of the embodiments of this invention is to provide a semiconductor device that reduces electrical capacity between the semiconductor substrate and penetrating via in comparison with the usual model.

According to one of the embodiments of this invention, a semiconductor device is provided such that a penetrating via with conductive material embedded through the insulating film is formed in the through hole of the semiconductor substrate of a first conductivity type. The semiconductor device includes a well of a second conductivity type on the upper section of the semiconductor substrate in the vicinity of the penetrating via; a first electrode connected to the well; and a second electrode connected to the semiconductor substrate.

### First Embodiment

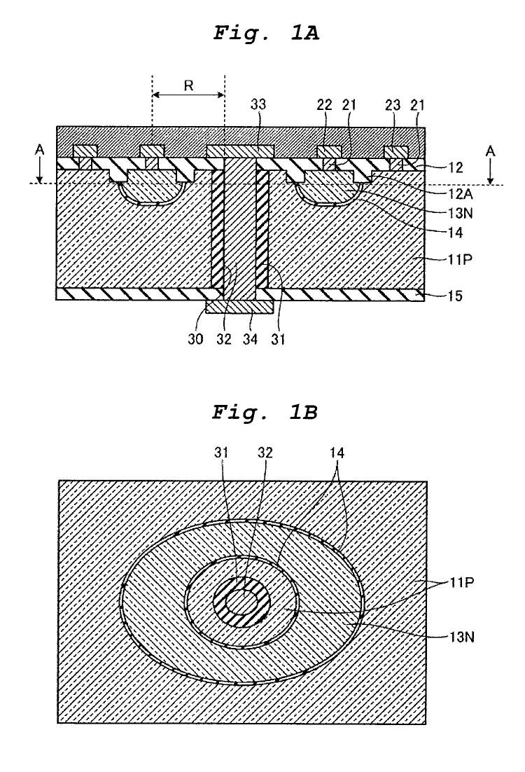

FIGS. 1A and 1B are the schematic diagrams of the structure of the semiconductor device in the first embodiment, FIG. 1A is a partial lateral sectional view, FIG. 1B is a sectional view of FIG. 1A at A-A. The semiconductor devices are semiconductor chips with components such as memory cells configuring a NAND type flash memory formed on a p-type semiconductor substrate 11P. The memory cell unit, or other devices such as logic devices for control and access of the memory arrays do not directly relate with this embodiment so the diagrams are omitted. Likewise, the invention is equally applicable to non-memory cell devices, where chip stacking is contemplated.

On each of the upper surface and the back surface of the p-type semiconductor substrate 11P, insulating films 12, 15 composed of a silicon oxide film, are formed. At a designated position of the p-type semiconductor substrate 11P, a through hole 30 is formed penetrating perpendicular to the substrate, the designated position being a position where a through hole will not interfere with devices formed on the substrate. On the interior of the through hole 30, an insulating film 31 composed of silicon oxide film and the like, with a thickness of dozens of nm to several μm, is formed. A through via 32 stud composed of electric conductors is embedded into the through hole 30 where the insulating film 31 is formed. Via pads 33, 34 are formed on the front surface where components of the p-type semiconductor substrate 11P are formed and on the back surface or opposite side of the substrate, to overlay and electrically interconnect to the opposed ends of the through via 32. These via pads 33, 34 are positioned to be connected with via pads 33, 34 from another semiconductor device and thereby form a stacked or laminated type semiconductor device. Here, the thickness of the p-type semiconductor substrate 11P is set to 20 μm, and the diameter of the penetrating via 32 as 10 μm.

In the first embodiment, an n-type well 13N of opposite conductivity type to the substrate conductivity, is formed near the upper surface of the p-type semiconductor substrate 11P around the penetrating via 32. The depth of the n-type well 13N is approximately 1 to 2 μm. A component isolation insulating film 12A composed of a silicon oxide film is formed near the upper section of the p-type semiconductor substrate 11P at the border of the p-type semiconductor substrate 11P and the n-type well 13N. This component isolation insulating film 12A is provided as necessary to isolate the wells and the via from electrical connection from an overlying film thereon.

As shown in FIG. 1B, in planar view, the n-type well 13N has a ring shaped form with the penetrating via 32 at the center. Although it is torroidal in FIG. 1B, it may be a surrounding polygonal wall like structure. By forming the n-type well 13N on the p-type semiconductor substrate 11P, a depletion layer 14 is formed at the p-n junction section.

In one section in the region where the n-type well 13N is formed, an electrode 22 is provided through a contact 21 which extends through the insulating film 12. In one section in the p-type semiconductor substrate 11P near the n-type well 13N, an electrode 23 is provided as well through the contact 21 which extends through the insulating film 12. These electrodes 22, 23 are installed to apply a certain amount of voltage for the p-n junction between the p-type semiconductor substrate 11P and the n-type well 13N to be in a reverse bias state, while a component that constitutes the semiconductor device (not shown) is operating which will later be described. The electrodes 22, 23 are configured and arranged in such a way that the distance from the electrode 23 to the penetrating via 32 is longer compared to the distance R from the electrode 22 to the penetrating via 32.

Now, the operation of such a structured semiconductor device will be explained. The depletion layer 14 is formed near the p-n junction section at the border of the p-type semiconductor 11P and the n-type well 13N. This depletion layer 14 is the region where the semiconductor current carrier is insufficient. In the p-n junction, current will flow from the p-type semiconductor to the n-type semiconductor but current will not flow in the reverse direction. Again, the insulating films 12, 15, 31 formed in between the p-type semiconductor substrate 11P and the penetrating via 32, the and the via pads 33, 34 has a thickness of dozens of nm to several μm; the electrical capacity in between the penetrating via 32, the via pads 33, 34 and the p-type semiconductor substrate 11P ranges from several hundred fF to several pF, a large electrical capacity.

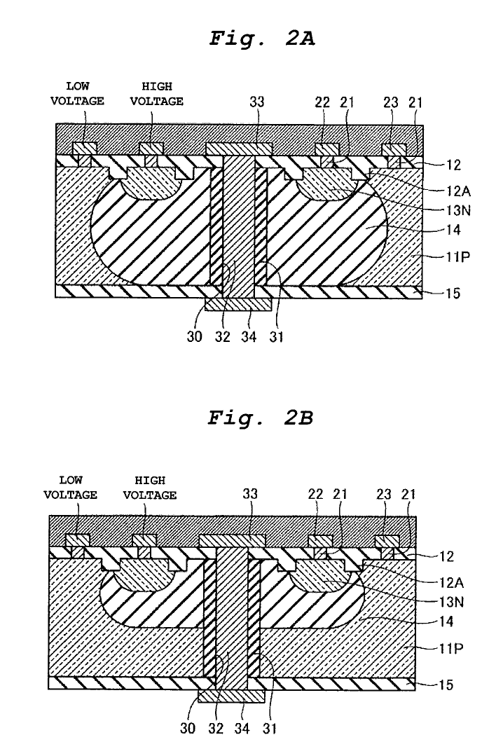

In the structure of the semiconductor device in the first embodiment, dozens of volts are applied to the electrode 22 connected to the n-type well 13N, and the electrode 23 connected to the p-type semiconductor substrate 11P is set to ground (zero volts). If the voltage applied to the n-type semiconductor is greater than the voltage applied to the p-type semiconductor (reverse bias state), then the depletion layer at the p-n junction boundary grows. FIGS. 2A and 2B are the schematic diagram of the condition where reverse bias is applied to the p-n junction. As shown in FIG. 2A, the depletion layer 14 grows to extend across the thickness of the p-type semiconductor substrate 11P up to the back surface thereof 11P when reverse bias voltage is applied to the electrodes 22, 23 (higher voltage applied to the electrode 22 compared to the electrode 23) of the semiconductor device with the p-type semiconductor substrate 11P of thickness 20 μm, and the diameter of the penetrating via 32 is 10 μm. As shown in FIG. 1B, the region surrounding the penetrating via 32 is enclosed within the depletion layer 14 due to the n-type well 13N placed to surround the penetrating via 32. In this state, the depletion layer 14 acts as a thick insulating layer due to insufficient current carrier capacity, and thus the electric capacitance between the penetrating via 32, the via pad 33, 34 and the p-type semiconductor substrate 11P decreases rapidly compared with the situation in FIGS. 1A and 1B.

FIG. 2B is the case when smaller voltage is applied to the electrodes 22, 23 compared to that of FIG. 2A. In this case, the depletion layer 14 is shorter compared to that in FIG. 2A, it does not grow up to the back surface of the p-type semiconductor substrate 11P. However, due to applying reverse bias voltage, the depletion layer 14 is formed at a section of the surroundings of the penetrating via 32, thus the depletion layer 14 acts as a thick insulating layer in that location. In this case, although the effect of decrease in electric capacity between the penetrating via 32, the via pad 33, 34 and the p-type semiconductor substrate 11P is reduced compared to that of FIG. 2A, it is enough to lower the electric capacitance around the via 32 compared to a conventional structure.

When applying a reverse bias voltage to the electrodes 22, 23, other component structures of the semiconductor device must at least be working. In the case when other components are working, certain voltage is applied in between the electrodes 22, 23. That is, when other components are working, voltage applied to electrodes 22, 23 will not be switched on/off. This is to stably form the depletion layer 14 of a designated thickness around the penetrating via 32.

Additionally, in order to form the depletion layer 14 surrounding the penetrating via 32, to decrease electric capacitance by applying reverse bias, it is desired to have the position of the n-type well 13N (distance R from the lateral surface of the penetrating via 32 to the electrode 22 installed on the n-type well 13N) be within the designated range from the penetrating via 32. This range may change due to the thickness of the substrate, voltage to be applied, and the amount of n-type impurity ion in the n-type well 13N. Generally, when dozens of volts of reverse bias voltage is applied to the electrodes 22, 23, the depletion layer 14 is known to grow roughly dozens of μm. Therefore, it is desired to install the n-type well 13N within the range of the thickness of the p-type semiconductor substrate 11P from the penetrating via 32. Because within this kind of range, when reverse bias voltage is applied, the depletion layer 14 will extend to the penetrating via 32.

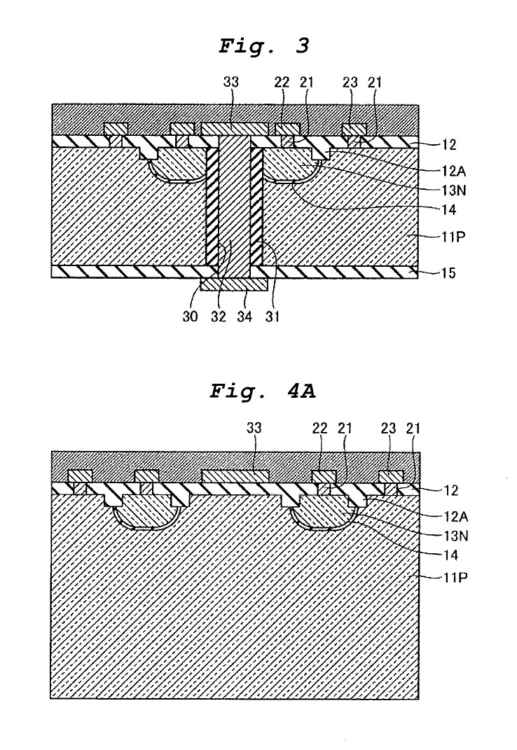

FIG. 3 depicts the schematic sectional view of another configuration example of the semiconductor device in the first embodiment. This diagram shows the n-type well 13N and the penetrating via 32 are arranged adjacently. However, in this embodiment the n-type well 13N is not spaced from, but in contact with, the insulating film 31. For identical components to that of FIGS. 1A and 1B, identical letters and numerals are used and explanations are omitted.

Even with this kind of structure, by applying reverse bias voltage to the electrodes 22, 23, the depletion layer 14 grows from the bottom of the n-type well 13N. The depletion layer 14 is not formed on the portion of the n-type well 13N in contact with the penetrating via 32, but the depletion layer 14 formed below the n-type well 13N acts as a thick insulating layer, thus similar to the previous structure, electric capacitance between the penetrating via 32, the via pad 33, and the p-type semiconductor substrate 11P, can be decreased.

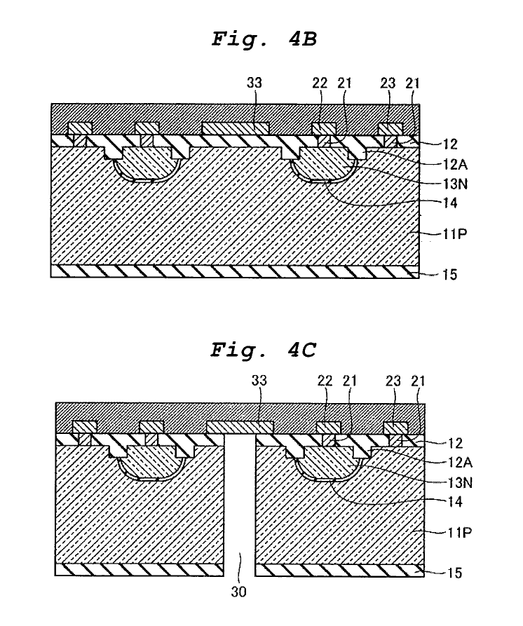

The manufacturing method of the semiconductor device structured this way will now be explained. FIGS. 4A to 4E depict the schematic sectional views of an example of the procedure of the manufacturing method of the semiconductor device in the first embodiment. First, as shown in FIG. 4A, using well known semiconductor manufacturing processes, components of the semiconductor device (not shown), such as transistor circuits and gate circuits, are formed on the p-type semiconductor substrate 11P. Simultaneously, a via pad 33 is formed on the upper section of the p-type semiconductor substrate 11P adjacent to the device region where the penetrating via 32 will be formed in a later process. Additionally, the n-type well 13N is formed on the upper surface of the p-type semiconductor substrate 11P surrounding the pad 33. The component isolation insulating film 12A may be formed, as required, at the border of the p-type semiconductor substrate 11P and the n-type well 13N within a designated depth from the upper surface of the substrate. This component isolation insulating film 12A is generally called STI (Shallow Trench Isolation). The n-type well 13N is connected to an electrode 22 by the contact 21. The p-type semiconductor substrate 11P is connected to an electrode 23 by the contact 21 as well.

Thereafter, as shown in FIG. 4B, the back surface of the p-type semiconductor substrate 11P is ground to a desired thickness (for example 20 μm) is reached, and then the insulating film 15 is formed on the back surface of the p-type semiconductor substrate 11P. This insulating film 12 can be formed using a method such as the CVD method. Next, as shown in FIG. 4C, resist is applied to the back surface of the p-type semiconductor substrate 11P to form resist patterns to open the forming position of the penetrating via 32; this resist pattern is used as a mask to form the through hole 30 by the etching method that penetrates through the p-type semiconductor substrate 11P in the perpendicular direction. This through hole 30 corresponds with the position of the via pad 33 formed on the surface of the p-type semiconductor substrate 11P and is placed to communicate with the via pad 33. Next, as shown in FIG. 4D, a thin film forming method, such as the CVD method, is used to form the insulating film 31 composed of silicon oxide film (for example) on the interior of the through hole 30. Additionally, as shown in FIG. 4E, a method such as the sputtering method or the electroplating method is used to embed conductive material such as Cu within the through hole 30 to form the penetrating via 32.

Thereafter, the via pad 34 is formed on the back surface of the penetrating via 32 on the back side of the p-type semiconductor substrate 11P. By this, the semiconductor device structured as shown in FIG. 1A is obtained.

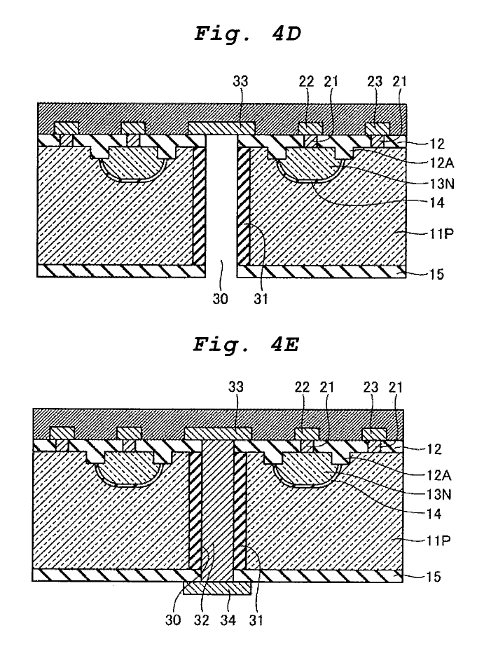

Although the n-type well 13N is formed on the p-type semiconductor substrate 11P, the conductivity type may be reversed. FIG. 5 depicts the schematic sectional view of another configuration example of the semiconductor device in the first embodiment. In this diagram, the n-type semiconductor substrate 11N, such as an n-type silicon substrate, and a p-type well 13P are formed into the upper surface of the n-type semiconductor substrate 11N near the penetrating via 32. In this example, voltage applied to the electrode 23 connected to the n-type semiconductor substrate 11N is higher than the voltage applied to the electrode 22 connected to the p-type well 13P. When reverse bias voltage is applied to the electrodes 22, 23 as shown in the FIG., the depletion layer 14 reaches and surrounds the penetrating via 32 which, acts the same way as forming an insulating layer, and electric capacitance between the penetrating via 32, the via pad 33, 34 and the p-type semiconductor substrate 11P is decreased.

In the first embodiment, a well of opposite conductivity type to that of the substrate is formed on the upper section of the semiconductor substrate surrounding the penetrating via 32, and then reverse bias voltage is applied in between the electrode 22 which is connected to the well and the electrode 23 connected to the semiconductor substrate. From this, the depletion layer 14 formed at the border of the semiconductor substrate and the well will grow towards the back surface of the semiconductor substrate, acting as a thick insulating layer. As a result it enables reducing electric capacitance between the penetrating via 32, via pad 33, 34 and semiconductor substrate, and has an effect to reduce signal wave form drop even if a high frequency electrical signal is transmitted to the penetrating via 32.

### Second Embodiment

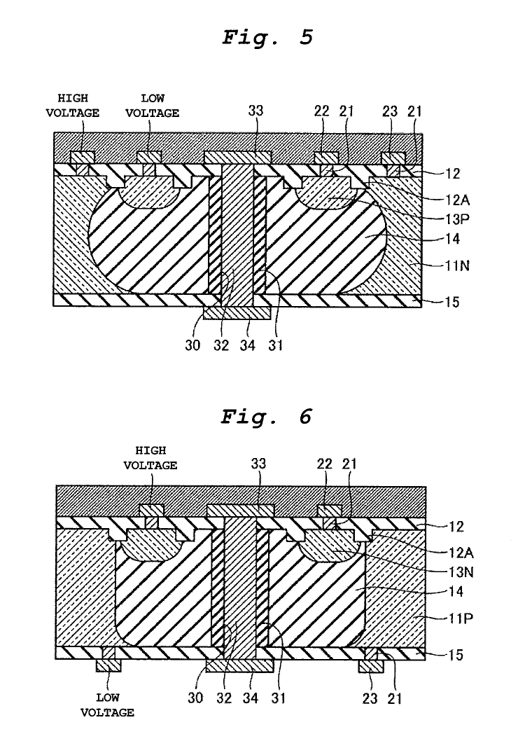

FIG. 6 depicts the schematic diagram of the structure of the semiconductor device in the second embodiment. This semiconductor device is structured so the electrode 23 connected to the front side of the p-type semiconductor substrate 11P FIGS. 1A and 1B of the first embodiment is moved to the back side of the semiconductor substrate 11P. In this case, the electrodes 22, 23 are also installed in such a way that the distance from the electrode 23 to the penetrating via 32 is longer compared to the distance R from the electrode 22 to the penetrating via 32. For identical components to that of FIGS. 1A and 1B, identical letters and numerals are used and explanations are omitted. Again, even with this kind of structure, by applying reverse bias voltage to the electrodes 22, 23, the depletion layer 14 grows to cover the surrounding area of the penetrating via 32. As a result, the second embodiment will have similar effects to that of first embodiment.

### Third Embodiment

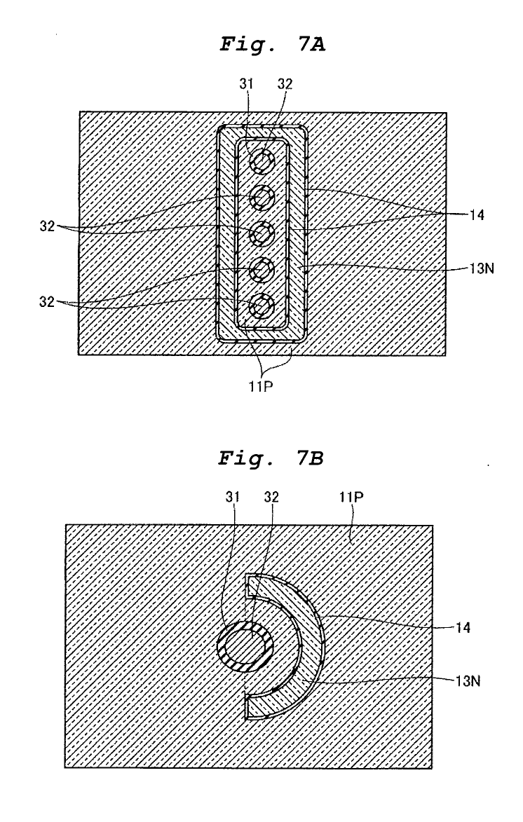

FIGS. 7A and 7B are the schematic plane sectional view of the structure of the semiconductor device in the third embodiment. In the first embodiment, a well of opposite conductivity type to that of the semiconductor substrate is formed on the upper section of the semiconductor substrate surrounding a single penetrating via. In the third embodiment, as shown in FIG. 7A, the n-type well 13N may be placed on the upper section of the p-type semiconductor substrate 11P to surround plural penetrating vias 32. In the example in FIG. 7A, the n-type well 13N is placed above the p-type semiconductor substrate 11P surrounding the five linearly arranged penetrating via 32. Even with this kind of structure, by applying reverse bias voltage in between the p-type semiconductor substrate 11P and the n-type well 13N, the depletion layer 14 will grow to surround the respective penetrating via 32, and enables reducing electric capacity between the penetrating via 32, the via pad 33, 34 and the p-type semiconductor substrate 11P.

Additionally, in the first embodiment, a ring shaped well surrounds the penetrating via adjacent to the front surface of semiconductor substrate 11P. However, in cases where other components are placed in the vicinity of the penetrating via, it is difficult to form a well to surround the penetrating via. In such case, as shown in FIG. 7B, the n-type well 13N may be formed on the top part of p-type semiconductor substrate 11P that is in the vicinity of the penetrating via 32 in such a way that it is adjacent to, but does not surround, the penetrating via 32. In the case of FIG. 7B, the n-type well 13N is formed in a semicircular arc having the penetrating via 32 at the center of the arc. This is only an example and does not need to be semicircular, other forms are also acceptable. Even when the isolated n-type well is placed in the vicinity of the penetrating via 32, by applying reverse bias voltage between the p-type semiconductor substrate 11P and the n-type well 13N, the depletion layer 14 grows to reach, and extend around, the penetrating via 32 from the n-type well 13N, and reduce electrical capacitance between the penetrating via 32, the via pad 33, 34 and the p-type semiconductor substrate 11P.

By the third embodiment, similar effects may be obtained as in the first embodiment.

In addition, although the example above shows the case of applying the third embodiment to the first embodiment, third embodiment may also be applied to the second embodiment.

Although the second and third embodiments describes the example of forming the n-type well 13N on the p-type semiconductor substrate 11P, similar to the first embodiment, the p-type well 13P may be formed in an n-type semiconductor 11N.

While certain embodiments have been described, these embodiments have been presented by way of example only, and are not intended to limit the scope of the inventions. Indeed, the novel embodiments described herein may be embodied in a variety of other forms. Furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate of a first conductivity type;
a via formed through the semiconductor substrate of the first conductivity type, and an insulating film disposed in the via and extending along at least a portion of the surface of the via from a first surface to a second opposed surface of the semiconductor substrate of the first conductivity type;
a well of a second conductivity type disposed adjacent a first face of the semiconductor substrate adjacent to the via and extending at least partially around the via;
a first electrode connected to the well; and
a second electrode connected to the semiconductor substrate.

2. The semiconductor device of claim 1, further including a conductive stud extending through the via, the conductive stud at least partially surrounded by the insulating film.

3. The semiconductor device of claim 2, further including a depletion layer extending from the second conductivity region within the semiconductor substrate of the first conductivity type and contacting at least a portion of the wall of the via.

4. The semiconductor device of claim 3, further including a power supply capable of providing a lower bias potential to the second electrode as compared to the bias provided to the first electrode by the power supply.

5. The semiconductor device of claim 4, wherein the bias potential on the second electrode is at ground potential.

6. The semiconductor device of claim 4, wherein the well surrounds the via.

7. The semiconductor device of claim 6, further including a region of the semiconductor substrate of the first conductivity device interposed between the well and the via.

8. The semiconductor device of claim 6, wherein at least a portion of the well contacts the sidewall of the via.

9. The semiconductor device of claim 4, further including a second layer of insulating material overlying the contacts.

10. The semiconductor device of claim 4, further including a pad formed over each of the opposed ends of the via and in electrical contact with the conductive stud.

11. The semiconductor device of claim 4, further including a second current flowing through the stud.

12. A method of changing the capacitance surrounding a through via in a semiconductor substrate of a semiconductor device, comprising:
providing a conductive stud capable of conducting signal current through the via;
insulating the stud from the sidewalls of the via; and
selectively forming a depleted region in the semiconductor substrate adjacent to the via.

13. The method of claim 12, further including forming a well structure of a conductivity type opposite the conductivity type of the semiconductor substrate in the semiconductor substrate directly adjacent to, and at least partially surrounding, the via.

14. The method of claim 13, further including providing a second terminal in electrical contact with the semiconductor substrate and a first terminal in electrical contact with the well, and wherein the well is disposed intermediate of the via and the first contact.

15. The method of claim 14, further including imposing a bias on the first terminal whish has a higher positive potential than a bias present on the second terminal.

16. The method of claim 15, wherein the second terminal is grounded.

17. The method of claim 16, wherein the bias imposed on the first terminal having a higher positive potential than the ground potential of the second terminal causes a depletion region to form adjacent to the via.

18. The method of claim 17, wherein the well surrounds the via, and the depletion region surrounds the region.

19. A semiconductor device comprising:
a substrate of a first conductivity type having a first surface and an opposed second surface;
a via extending through the semiconductor substrate from the first to the second surfaces thereof;
an insulator layer formed on the interior surfaces of the via;
a conductive stud extending through the via in contact with, and insulated from the via wall by, the insulator layer;
a conductive pad extending over the opposed ends of the conductive stud and adjacent regions of the first and the second surfaces of the semiconductor substrate;
a well, of a second conductivity type opposite to the first conductivity type of the substrate, extending inwardly of the first face of the substrate and surrounding the via;
a first terminal in electrical contact with the well; and
a second terminal extending into electrical contact with the semiconductor substrate, such that the well is located between the position of the second terminal and the via.

20. The method of claim 19, wherein the second terminal is located on the second surface of the substrate.
